(19) United States
(12) Patent Application Publication
(10) Pub. No.: US 2019/0279934 A1
(43) Pub. Date: Sep. 12, 2019

(54) COMPLEMENTARY METAL OXIDE SEMICONDUCTOR WITH DUAL CONTACT LINERS

(71) Applicant: International Business Machines Corporation, Armonk, NY (US)

(72) Inventors: Peng Xu, Santa Clara, CA (US); Kangguo Cheng, Schenectady, NY (US)

(21) Appl. No.: 15/914,506

(22) Filed: Mar. 7, 2018

(51) Int. Cl. H01L 23/535; H01L 21/768; H01L 27/092

(52) U.S. Cl. CPC H01L 23/535; H01L 21/76847; H01L 27/092; H01L 21/76895

(57) ABSTRACT

The present disclosure relates to a complimentary-metal oxide semiconductor (CMOS) device with dual contact liners. The device can comprise a first field effect transistor comprising a first liner comprising a first portion and a second portion, wherein the first liner resides in a first trench region that is defined by a first spacer and a first epitaxial region (e.g., NFET epitaxial region). The device can also comprise a second field effect transistor comprising a second liner that resides in a second trench region that is defined by a second spacer and a second epitaxial region, wherein the second portion comprises a first material, and the first portion and the second liner comprise a second material.

### BACKGROUND

The subject disclosure relates to semiconductor device structures and assembly, and more specifically, to a complementary metal oxide semiconductor with dual contact liners, and the fabrication thereof.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later.

In accordance with one or more example embodiments described herein, a complementary metal oxide semiconductor (CMOS) cell with dual contact liners is provided. The CMOS cell can comprise a first field effect transistor (e.g., an n-type field effect transistor, (NFET)) comprising a first liner. The first liner can comprise a first portion (e.g., a top portion) and a second portion (e.g., a bottom portion), wherein the first liner resides in a first trench region that is defined by a first spacer and a first epitaxial region (e.g., NFET epitaxial region). The CMOS cell also comprises a second field effect transistor (e.g., a p-type field effect transistor (PFET)) comprising a second liner that resides in a second trench region that is defined by a second spacer and a second epitaxial region (e.g., PFET epitaxial region). The second portion of the first liner comprises a first material (e.g., titanium). The first portion and the second liner comprise a second material (e.g., a nickel-platinum alloy). Additionally, both the first trench region and the second trench region can be filled with a metal (e.g., tungsten or cobalt). The CMOS cell can further comprise a first substrate associated with the first field effect transistor, and a second substrate associated with the second field effect transistor, wherein the first epitaxial region is in contact with the first substrate, and the second epitaxial region is in contact with the second substrate.

According to one or more other example embodiments described herein, a CMOS cell can comprise a first field effect transistor (e.g., NFET) comprising a first liner that resides in a first trench region that is defined by a first spacer and a first epitaxial region (NFET epitaxial region). The CMOS cell can also comprise a second field effect transistor (e.g., PFET) comprising a second liner that resides in a second trench region that is defined by a second spacer and a second epitaxial region, wherein the first liner comprises a first material (e.g., titanium) and the second liner comprises a second material (e.g., nickel-platinum alloy). Both the first trench region and the second trench region can be filled with a metal (e.g., tungsten or cobalt). The CMOS cell can further comprise a first substrate associated with the first field effect transistor, and a second substrate associated with the second field effect transistor, wherein the first epitaxial region is in contact with the first substrate, and the second epitaxial region is in contact with the second substrate.

According to one or more example embodiments described herein, a method is provided. An example, non-limiting method (e.g., operations) that facilitates assembly of a CMOS cell can comprise lining a first trench region of a first field effect transistor (e.g., n-type field effect transistor, or NFET) with a first liner comprising a first portion (e.g., a top portion) and a second portion (e.g., a bottom portion), wherein the first trench region is defined by a first spacer and a first epitaxial region (e.g., NFET epitaxial region). The example method can further comprise lining a second trench region of a second field effect transistor (e.g., a p-type field effect transistor, or PFET) with a second liner (e.g., a nickel-platinum liner), wherein the second trench region is defined by a second spacer and a second epitaxial region (PFET epitaxial region), and wherein the second portion comprises a first material (e.g., titanium), and the first portion and the second liner comprise a second material (e.g., nickel-platinum alloy). Both the first trench region and the second trench region can be filled with a metal (e.g., tungsten or cobalt).

### BRIEF DESCRIPTION OF THE DRAWINGS

FIGS. 1A-1F illustrate cross sectional views of an example method for fabricating a complementary metal-oxide-semiconductor (CMOS) cell with dual contact liners that results in a first trench region associated with the first field effect transistor of the cell being pinched off.

FIG. 2 illustrates a cross-sectional view of a CMOS cell in its initial stages of fabrication, with the CMOS cell comprising a first field effect transistor (e.g., an NFET) having a first substrate, and a first trench region lined with a first spacer. Also depicted is a second field effect transistor (e.g., a PFET) having a second substrate, and second trench region lined with a second spacer, in accordance with one or more embodiments described herein.

FIG. 3 illustrates a cross-sectional view of the CMOS cell in a fabrication stage wherein the NFET has been covered with a mask (first mask), while the part of the second spacer of the PFET contacting the second substrate has been etched to expose the second substrate for epitaxial growth on the second substrate, in accordance with one or more embodiments described herein.

FIG. 4 illustrates a cross-sectional view of the CMOS cell in a fabrication stage wherein an epitaxial region of the PFET (PFET epitaxial region) is in contact with the second substrate, in accordance with one or more embodiments described herein.

FIG. 5 illustrates a cross-sectional view of the CMOS cell in a fabrication stage wherein a film (e.g., silicon nitride, amorphous carbon) can line the walls of each trench region, resulting in a first film and second film, in accordance with one or more embodiments described herein.

FIG. 6 illustrates a cross-sectional view of the CMOS cell in a fabrication stage wherein the PFET is covered by a mask (second mask), in accordance with one or more embodiments described herein.

FIG. 7 illustrates a cross-sectional view of the CMOS cell in a fabrication stage wherein the first film is removed from the NFET, while the second film of the PFET is protected by the second mask, in accordance with one or more embodiments described herein.

FIG. 8 illustrates a cross-sectional view of the CMOS cell in a fabrication stage wherein the part of the first spacer in contact with the first substrate has been etched to expose the first substrate of the NFET, in accordance with one or more embodiments described herein.

FIG. 9 illustrates a cross-sectional view of the CMOS cell in a fabrication stage wherein an epitaxial region (NFET epitaxial region) is contact with the first substrate, in accordance with one or more embodiments described herein.

FIG. 10 illustrates a cross-sectional view of the CMOS cell in a fabrication stage wherein a first conformal liner (e.g., oxide material) lines the first trench region, while a second conformal liner pinches off the second trench region opening, in accordance with one or more embodiments described herein.

FIG. 11 illustrates a cross-sectional view of the CMOS cell in a fabrication stage wherein the first conformal liner associated with the NFET is removed from the first trench region, while a remnant of the second conformal liner is left behind in the second trench region, in accordance with one or more embodiments described herein.

FIG. 12 illustrates a cross-sectional view of the CMOS cell in a fabrication stage wherein a titanium liner lines the first trench region, and also fills a divot area above the remnant of the second conformal liner, in accordance with one or more embodiments described herein.

FIG. 13 illustrates a cross-sectional view of the CMOS cell in a fabrication stage wherein the first trench region is filled with a metal (e.g., tungsten, cobalt, etc.), creating a first metallic filler in accordance with one or more embodiments described herein.

FIG. 14 illustrates a cross-sectional view of the CMOS cell in a fabrication stage wherein the titanium liner has been removed from the PFET, and the removal process has also removed a top part of the titanium liner in the NFET, in accordance with one or more embodiments described herein.

FIG. 15 illustrates a cross-sectional view of the CMOS cell in a fabrication stage wherein the remainder of the second conformal liner is etched away, in accordance with one or more embodiments described herein.

FIG. 16 illustrates a cross-sectional view of the CMOS cell in a fabrication stage wherein the second film associated with the PFET (e.g., silicon nitride) is also removed, in accordance with one or more embodiments described herein.

FIG. 17 illustrates a cross-sectional view of the CMOS cell in a fabrication stage wherein a nickel-platinum alloy can be deposited into the second trench region to form a nickel -platinum liner, and deposited into a divot area above the titanium liner of the NFET, in accordance with one or more embodiments described herein.

FIG. 18 illustrates a cross-sectional view of the CMOS cell in a fabrication stage wherein the second trench region is filled with a metal (e.g., tungsten, cobalt, etc.), creating a second metallic filler, in accordance with one or more embodiments described herein.

FIG. 19 illustrates a illustrates a cross-sectional view of the CMOS cell in a fabrication stage wherein the dummy gates of the NFET and PFET are replaced with metal gates, in accordance with one or more embodiments described herein.

FIG. 20 illustrates a cross-sectional view of another embodiment of a CMOS cell wherein a first sacrificial filler and a second sacrificial filler are used, in accordance with one or more embodiments described herein.

FIG. 21 illustrates a cross-sectional view of the CMOS cell in a fabrication stage wherein a second mask is applied to cover the second sacrificial filler, in accordance with one or more embodiments described herein.

FIG. 22 illustrates a cross-sectional view of the CMOS cell in a fabrication stage wherein the first sacrificial filler is removed, in accordance with one or more embodiments described herein.

FIG. 23 illustrates a cross-sectional view of the CMOS cell in a fabrication stage wherein the part of the first spacer in contact with the first substrate is removed, exposing the first substrate, in accordance with one or more embodiments described herein.

FIG. 24 illustrates a cross-sectional view of the CMOS cell in a fabrication stage wherein an NFET epitaxial region is grown onto the first substrate, in accordance with one or more embodiments described herein.

FIG. 25 illustrates a cross-sectional view of the CMOS cell in a fabrication stage wherein a titanium liner lines the first trench region, in accordance with one or more embodiments described herein.

FIG. 26 illustrates a cross-sectional view of the CMOS cell in a fabrication stage wherein the first trench region is filled with a metal (e.g., tungsten, cobalt), creating a first metallic filler, in accordance with one or more embodiments described herein.

FIG. 27 illustrates a cross-sectional view of the CMOS cell in a fabrication stage wherein the second sacrificial filler is removed from the second trench region, in accordance with one or more embodiments described herein.

FIG. 28 illustrates a cross-sectional view of the CMOS cell in a fabrication stage wherein a nickel-platinum alloy lines the second trench region, creating a nickel-platinum liner, in accordance with one or more embodiments described herein.

FIG. 29 illustrates a cross-sectional view of the CMOS cell in a fabrication stage wherein the second trench region is filled with a metal (e.g., tungsten, cobalt, etc.), creating a second metallic filler, in accordance with one or more embodiments described herein.

FIG. 30 illustrates a cross-sectional view of the CMOS cell in a fabrication stage wherein the dummy gates are replaced with metal gates, in accordance with one or more embodiments described herein.

FIG. 31 illustrates a flow diagram of an example, non-limiting method that relates to the assembly of a CMOS cell, in accordance with one or more embodiments described herein.

FIG. 32 illustrates a flow diagram of an example, non-limiting method related to the assembly and programming of another CMOS cell, in accordance with one or more embodiments described herein.

FIG. 33 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Complementary metal oxide semiconductor (CMOS) technology can be used in microprocessors, microcontrollers, static random access memory (RAM), and other digital circuits. CMOS technology can also be used in analog circuits such as image sensors (CMOS sensor), data converters, and highly integrated transceivers. Vertical transistors (e.g., vertical field effect transistors, or VFETs) are a potential device option to continue scaling complementary metal-oxide-semiconductor (CMOS) technology to five nanometer (5 nm) nodes, and beyond.

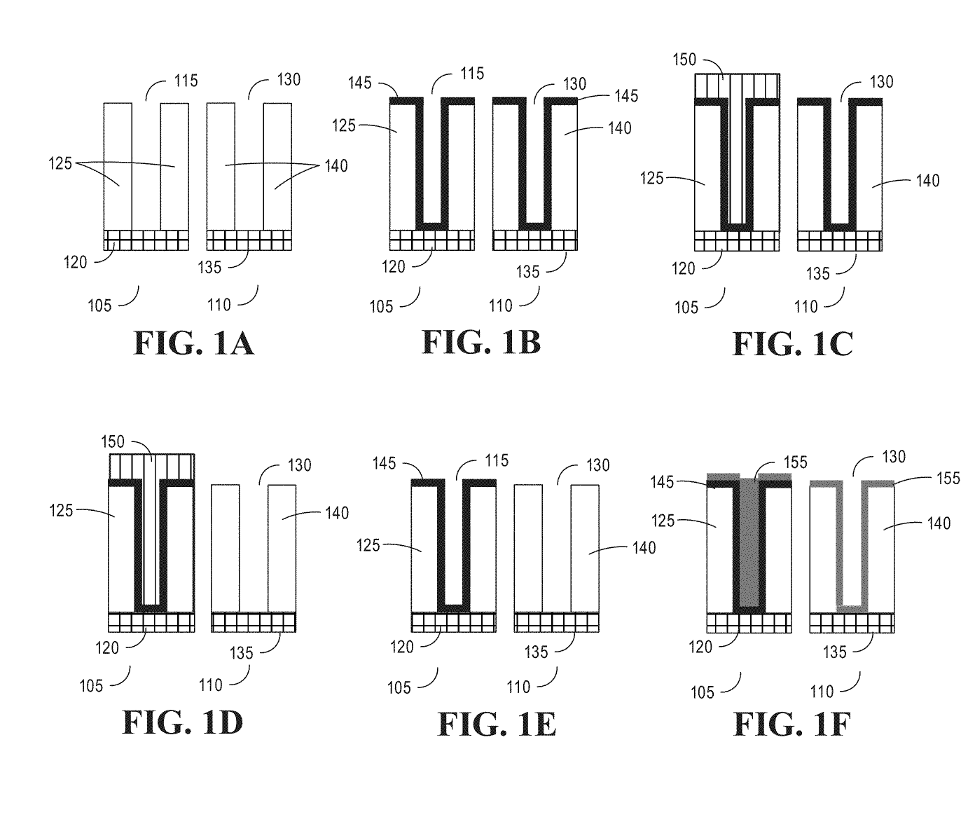

FIGS. 1A-1F depict a cross sections of an example embodiment of a CMOS cell 100 in accordance with example embodiments of the present application. The example CMOS cell 100 can have two types of transistors, both of which can be vertical field effect transistors (FETs), or both of which can be horizontal FETs. A first FET can be a first type of FET (n-type FET, or NFET), and the second FET can be a second type of FET (p-type FET, or FPET). The first field effect transistor is illustrated as NFET 105, and the second field effect transistor is illustrated as PFET 110, parts of each of which are shown in FIGS. 1A-1F. The NFET 105 can comprise a first trench region 115, defined by a first substrate 120 and first metal gate 125. The PFET 110 can comprise a second trench region 130, defined by a second substrate 135 and a second metal gate 140. The first trench region 115, when filled, can serve as a source/drain terminal, whereby, for example, an electric current can pass from this source/drain terminal through a semiconductor channel (which can be a first substrate 120 situated under the first dummy gate 210) to another source/drain terminal (on the other side of the channel, not shown). Likewise, the second trench region 130 can also serve as a source/drain terminal for the second FET.

In accordance with one or more example embodiments, to better optimize or enhance the performance for each type of transistor (e.g., NFET or PFET), the contact resistance between a metal contact to the semiconductor (e.g., doped source/drain in a semiconductor substrate), can be different for each type of transistor (NFET or PFET). A contact liner (also referred to as “liner” herein) and a metallic filler, can form an interface between the contact metal and the semiconductor (e.g., substrate). In example embodiments, the first trench region (e.g., first trench region 115) can be lined with a first liner that minimizes the contact resistance for the NFET, while a second liner of a second material that is different from the material of the first liner, can line the second trench region (e.g., second trench region 130) and minimize the contact resistance of the PFET. Once the resistance in each type of transistor is minimized, the current through each trench region can be increased, and performance can be enhanced.

As transistor dimensions have become smaller, the trench region has also become narrower. In accordance with one method, a first liner (e.g., first liner 145) can be deposited in both FETs' trenches as illustrated in FIG. 1B. As shown in FIG. 1C, a mask (e.g., mask 150) can be applied so as to cover the first trench region 115, including the first liner 145. Next, as shown in FIG. 1D, the first liner can be removed from the second trench region 130, while the mask 150 prevents the removal of the first liner 145 from the first trench region 115. Moving on to FIG. 1E, the mask 150 can be removed. In FIG. 1F, when a second liner (e.g., second liner 155) is deposited to line the second trench region 130, the result would be that the second liner 155 would be deposited along the confines of the second trench region 130, but can also result in the second liner 155 being deposited on the first liner 145. If no other steps or methods are implemented, the second liner 155 clogs the first trench region 115, because the first trench region 115 will receive two liner deposits, with the second liner 155 deposited over the first liner 145. Because of the narrowness of the trench, there can be this pinch-off problem, that is, the second liner 155 can clog the first trench region 115 to the point that the trench can no longer be filled with other material, such as a low-resistance metal (e.g., tungsten, cobalt, etc.).

In other example embodiments, in accordance with the present application, the clogging of the trench resulting in pinch-off, as shown in FIG. 1F, can be alleviated by including several additional steps during the assembly process.

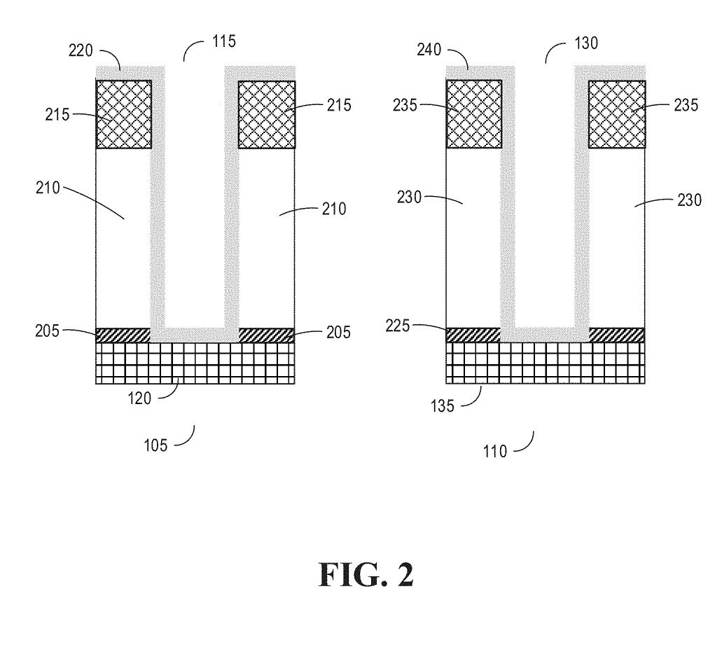

FIGS. 2-18 illustrates a method, in accordance with the present application, for assembling an apparatus that comprises a first field effect transistor (e.g., NFET) having a first liner that resides in a first trench region, and a second field effect transistor (e.g., PFET) comprising a second liner that resides in a second trench region. The first liner comprises a first portion (e.g., a top portion) of the first liner and a second portion (e.g., a bottom portion) of the first liner. The second portion comprises a first material, while the first portion and the second liner comprise a second material. The walls of first trench region are defined by a first spacer and the walls of the second trench region are defined by a second spacer. The bottom of the first trench region is defined by an epitaxial region, and the bottom of the second trench region is defined by another epitaxial region.

As shown in FIG. 2, the assembly of CMOS cell 100 can begin with the formation of a first trench region 115 and a second trench region 130 by etching through several layers of material. Referring to the resulting structure, the beginnings of a NFET (e.g., an NFET 105) can comprise a first substrate 120. In example embodiments, the first substrate 120 can comprise a silicon region, since it is the substrate for an NFET.

The NFET 105 at this stage can also comprise a first gate dielectric 205, which can comprise, for example, any suitable dielectric material such as silicon oxide, silicon nitride, silicon oxynitride, a high-k dielectric material. High-k dielectric materials are materials that have a high dielectric constant k. For example, silicon dioxide has a dielectric constant k of 3.9. Some examples of high-k dielectrics can be hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric can further include dopants such as lanthanum, aluminum, and magnesium. In some embodiments, the first gate dielectric 205 remain as the final gate dielectric of the transistor. In other embodiments, the first gate dielectric 205 is a dummy gate dielectric, and will be removed and replaced by a real gate dielectric in later processing.

The NFET 105 at this point in fabrication can also comprise a first dummy gate 210. The first dummy gate 210 serves as a physical placeholder that can be later replaced with a real gate that is a conductor, such as a metal gate. The first dummy gate 210 can comprise, for example, amorphous silicon (a-Si), amorphous silicon germanium (a-SiGe), etc. In other example embodiments, a real gate can be implemented from the start, as opposed to a first dummy gate 210.

The NFET 105 at this point can also comprise a first gate hardmask 215, which can serve to protect the first dummy gate 210 during the rest of the fabrication process. The first gate hardmask 215 will be removed in the final structure. In some example embodiments, the first gate hardmask 215 can be of one material. In other example embodiments, the first gate hardmask 215 can be comprised of multiple layers of different material. Hard masks can typically be comprised of, for example, silicon nitride (SiN), silicon oxynitride (SiON), silicon oxide (SiO), silicon oxycarbide (SiOC), silicon oxycarbonitride (SiOCN), silicoboron carbonitride (SiBCN), silicon carbon nitride (SiCN), or any suitable combination of those materials.

The NFET 105 at this stage can also comprise a first spacer 220, which can be formed from the deposit of spacer material into the first trench region 115 after formation of the first trench region 115 (and also the second trench region 130, subsequent to the formation of the second trench region 130). The first spacer 220 can comprise a dielectric material, such as silicoboron carbonitride (SiBCN), silicon oxycarbonitride (SiOCN), silicon carbon nitride (SiCN), silicon oxycarbide (SiOC), silicon oxynitride (SiON), etc., or any suitable combination of these materials. The first spacer 220 can be formed by any suitable technique (for example, by directional deposition).

Still referring to FIG. 2, the beginnings of a PFET 110 can be formed in a similar fashion to the formation of the initial stages of the NFET 105. Thus, the PFET 110 can, at this stage of fabrication, comprise a second substrate 135, a second gate dielectric 225, a second dummy gate 230, a second gate hardmask 235, and a second spacer 240. The components can be made of material similar to the corresponding components comprising the NFET 105. In the case of the PFET 110, the second substrate 135 can comprise a silicon germanium (SiGe) or silicon region, and further, isolation such as trench isolation (not shown) can be formed between the NFET and PFET. In some embodiments, the NFET and PFET are formed with the same material (e.g., silicon) on a substrate. In other embodiments, the NFET and PFET are formed on different materials (e.g., silicon for NFET, and SiGe for PFET) on a substrate (e.g., a silicon substrate). Different materials can be formed by using patterning techniques and epitaxy processes (e.g., SiGe in PFET region can be formed on a silicon substrate by using a hardmask to cover NFET region, recessing silicon substrate in PFET region to form a recess, filling the recess with SiGe by epitaxy growth).

Of note, the terms “first” and “second” can, for convenience and clarity, refer to components to provide context for which transistor the component is associated, and does not necessarily reflect that corresponding components are comprised of the same, or different, material. For example, the first spacer 220 and second spacer 240 might have been deposited during the same stage of fabrication, and thus could be of the same material, but the term “first” in first spacer 220 refers to the deposited spacer material associated with the NFET 105, while the term “second” in second spacer 240 refers to the deposited spacer material associated with the PFET 110.

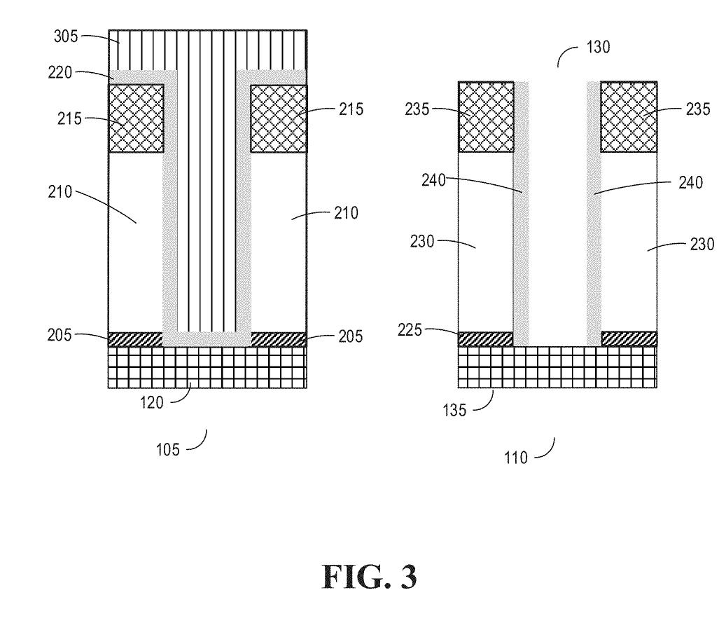

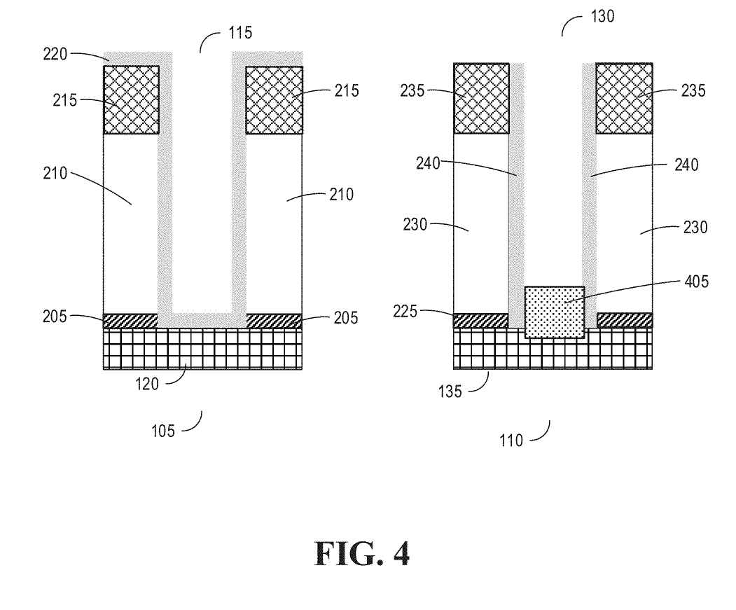

Moving on to more stages of the fabrication process, in FIG. 3, a first mask 305, which can be a photoresist, can be applied to cover the NFET 105, including filling the first trench region 115. The first mask 305 can serve to protect the NFET 105 while other components, or portions of components, of the PFET 110 are removed. Also in FIG. 3, the part of the second spacer 240 at the top of the PFET 110 is removed, for example using a reactive ion etch (RIE). The part of the second spacer 240 that had been in contact with the second substrate 135, is also removed, which exposes the second substrate 135 (e.g., semiconductor) in the second trench region 130, for growth of an epitaxial region, described in FIG. 4.

In FIG. 4, a PFET epitaxial region 405 is grown onto the second substrate 135, or optionally, grown and punched into the recessed, second substrate 135 (as depicted in FIG. 4), such that it is in contact with the second substrate 135. The PFET epitaxial region 405 can comprise, for example, boron-doped silicon germanium. Epitaxial material selectively grows on semiconductor material (e.g., the second substrate 135), but not on dielectric material (e.g., second spacer 240). The first mask 305 can be removed prior to the epitaxial growth of the PFET epitaxial region 405. No epitaxy growth occurs in the NFET at this stage because the first substrate 120 is covered by first spacer 220.

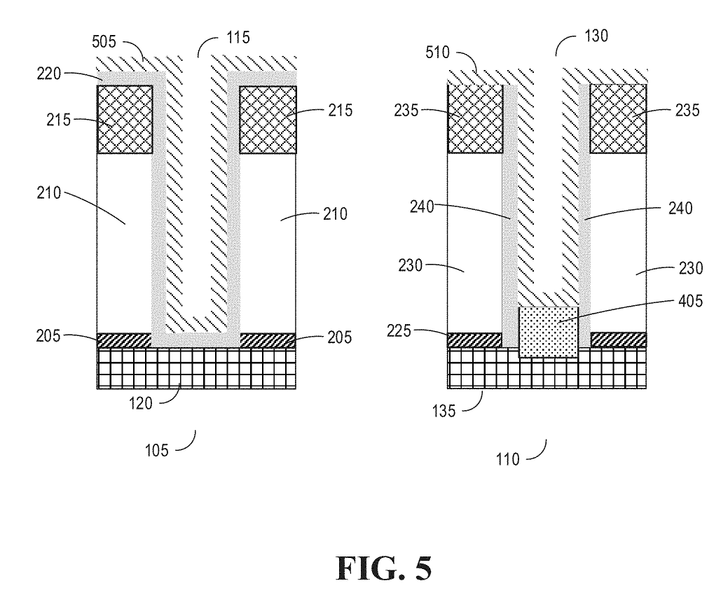

In FIG. 5, a film, which can comprise silicon nitride (SiN), or amorphous carbon, can be deposited over both FETS, such that the film lines top of the FETs and the walls of each trench. The deposit of the film can leave a first film 505 associated with the NFET 105 and a second film 510 associated with the PFET 110. The second film 510 can protect the PFET epitaxial region 405 in late fabrication stages. As mentioned above, the trenches' dimensions are small and narrow, with the openings' widths being approximately 15 nanometers (nm) to 20 nm, and the height of the trench is approximately 100 nm (e.g., high aspect ratio). The deposit of the film can still allow for a narrow opening of the trenches. The film thickness can be approximately 3 nm, making it easier to remove from a trench with a high aspect ratio.

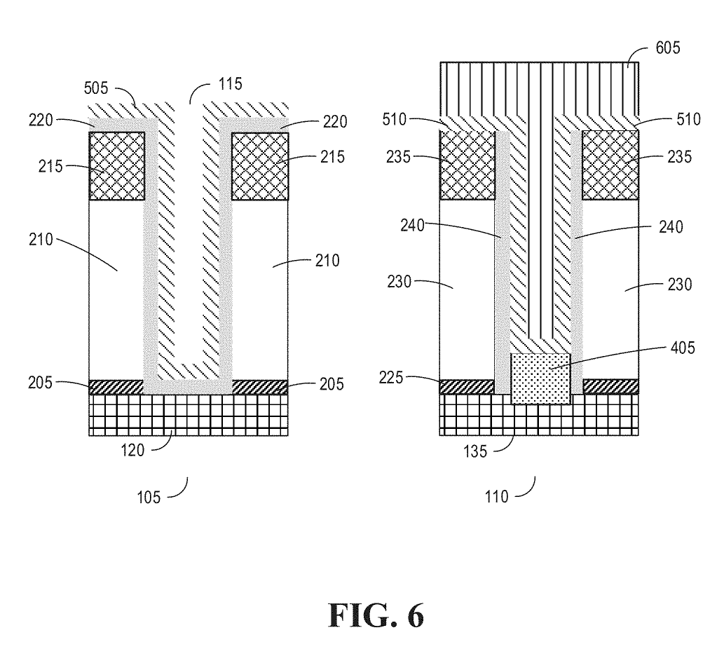

In FIG. 6, a second mask (e.g., second mask 605) can be applied so as to cover the PFET 110, which can serve to protect the PFET 110 during further fabrication processes as described below.

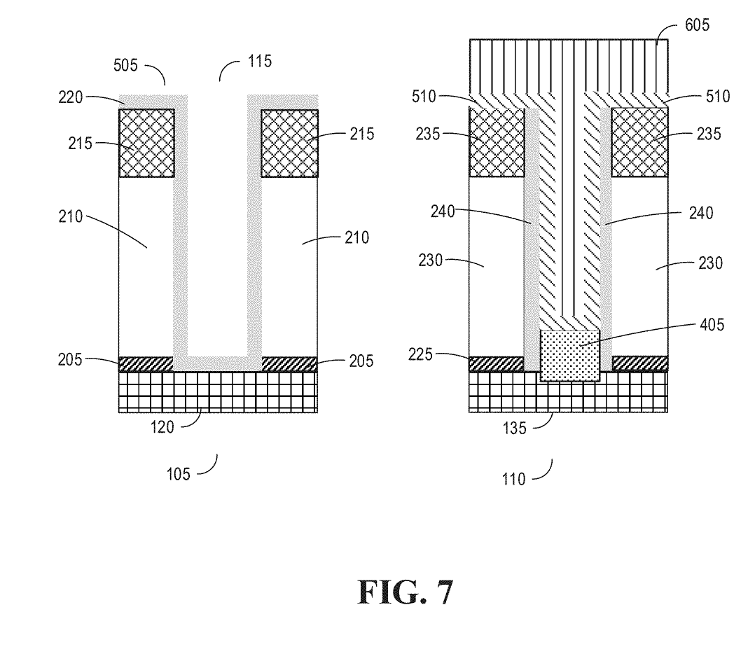

In FIG. 7, the first film 505 can be removed (for example, using an isotropic etch). The second mask 605 can prevent the second film 510 from being removed during the removal of the first film 505.

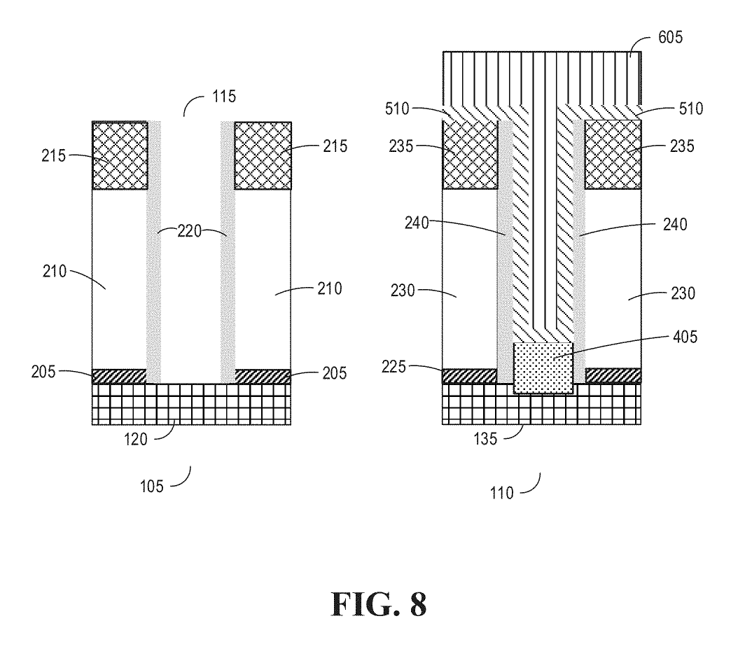

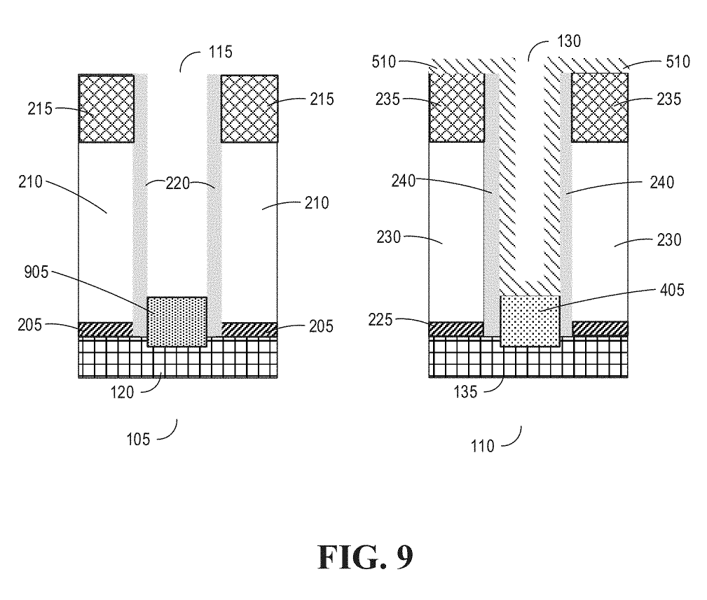

Similar to the process for FIG. 3, in FIG. 8, the part of the first spacer 220 on top of the NFET 105 can be removed, for example using a reactive ion etch (RIE). The part of the first spacer 220 contacting the first substrate 120 in the trench region is also removed, which exposes the first substrate 120 in the first trench region 115 for growth of an epitaxial region, described in FIG. 9.

Next, as shown in FIG. 9, a similar process to FIG. 4, the second mask 605 is first removed. Then, an NFET epitaxial region 905 can be grown onto the first substrate 120. Optionally, the NFET epitaxial region 905 can be grown and punched into the first substrate 120, wherein the first substrate 120 is recessed. The NFET epitaxial region 905 can comprise a material that is different from the PFET epitaxial region 405, for example, phosphorous doped silicon, or phosphorus and carbon doped silicon.

The absence of the first film 505, which was removed as described in FIG. 7, resulted in the opening in the first trench region 115 being larger than the opening in the second trench region 130.

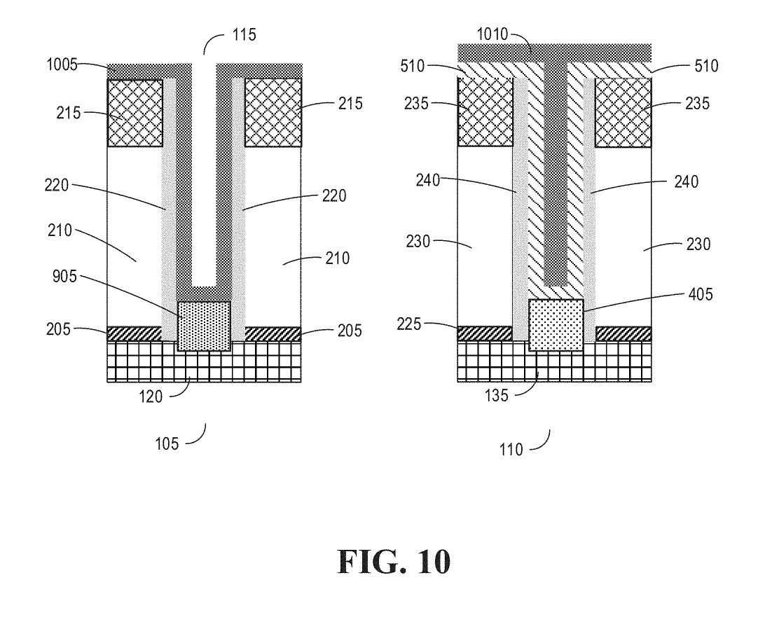

Moving on to FIG. 10, a conformal liner material (e.g., oxide) can be deposited so as to pinch off the second trench region 130 opening, while leaving an opening in the first trench region 115. This can be done, for example, using an oxide thickness that is less than half of the NFET trench opening, but greater than half of the trench opening of the PFET 110. This deposition results in a first conformal liner 1005 that lines the first trench region 115 and a second conformal liner 1010 that fills the second trench region 130. The deposition can result in complete fill of the second trench region 130 and partial fill of the first trench region 115.

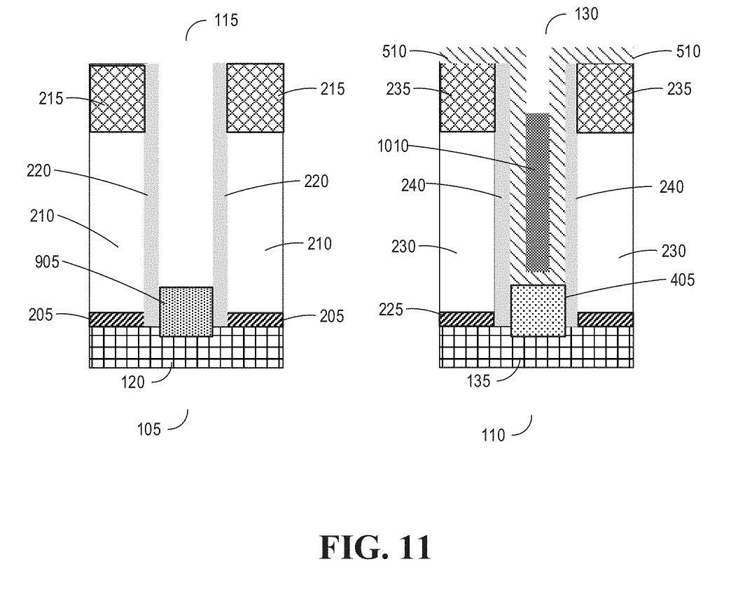

In FIG. 11, an isotropic etch of the conformal liner results in complete removal of the first conformal liner 1005 from the first trench region 115. In the second trench region 130, the second conformal liner 1010 is partially recessed from top. (FIG. 11)

Thus, as shown in FIG. 11, the result when the conformal liner material is etched back is that the first conformal liner 1005 is removed from the first trench region 115, while a remnant of the second conformal liner 1010 is left behind in the second trench region 130. A divot is left from where some of the second conformal liner 1010 was etched away, just above the remnant of the second conformal liner 1010.

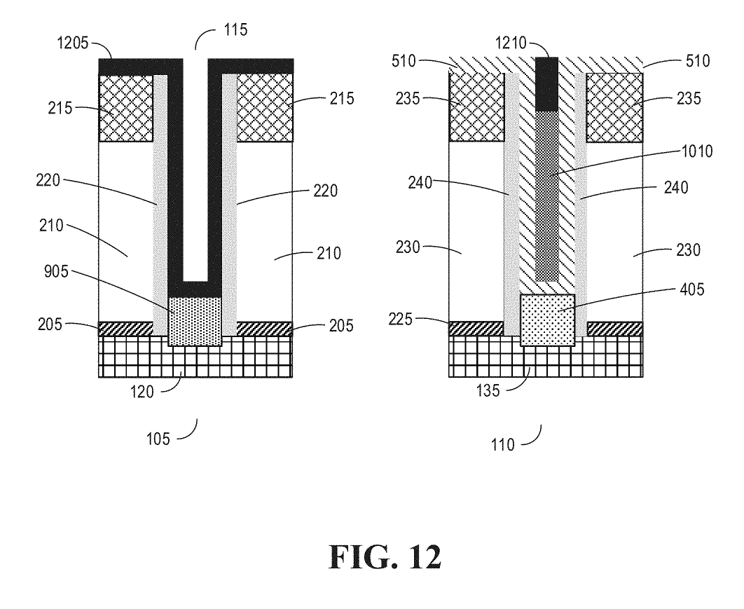

In FIG. 12, a layer of titanium is deposited so as to line the first trench region 115 with a titanium liner 1205. During this titanium liner 1205 deposition, the divot left behind from the etching away of the second conformal liner 1010 is also filled with titanium, resulting in a titanium divot fill 1210.

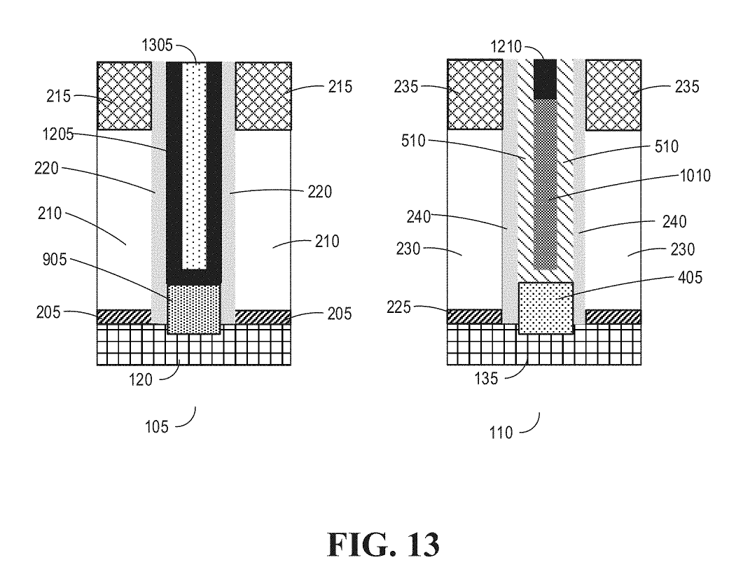

Referring now to FIG. 13, the first trench region 115 is filled with a metal (e.g., tungsten, cobalt, etc.), which creates a first metallic filler 1305 plugging the first trench region 115. Chemical mechanical planarization (CMP), which is also sometimes referred to as chemical mechanical polishing, can then be used to remove the parts of the titanium liner 1205, the second film 510, and the titanium divot fill 1210 at the top of the two FETs.

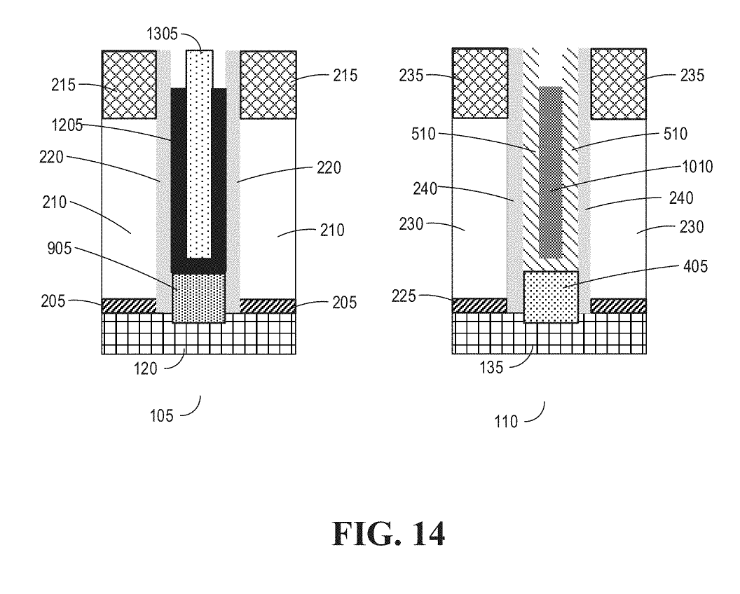

In FIG. 14, the remainder of the titanium divot fill 1210 is removed by etching, forming a divot above the second conformal liner 1010. However, the etching away of this titanium divot fill 1210 also results in a commensurate portion of the top of the titanium liner 1205 being etched away, forming divots above the titanium liner 1205.

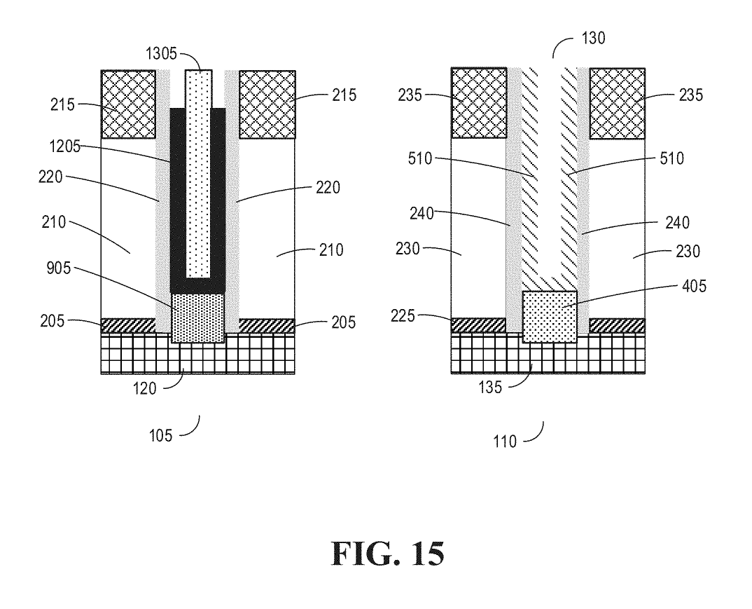

Moving to FIG. 15, the remainder of the second conformal liner 1010 is etched away, leaving a space in the second trench region 130 defined by second film 510.

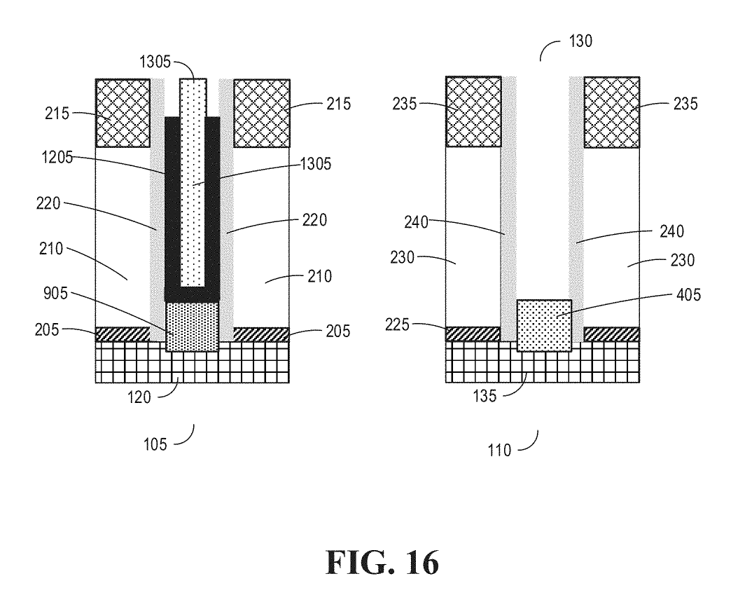

In FIG. 16, the second film 510 (e.g., silicon nitride) is also removed from the PFET 110.

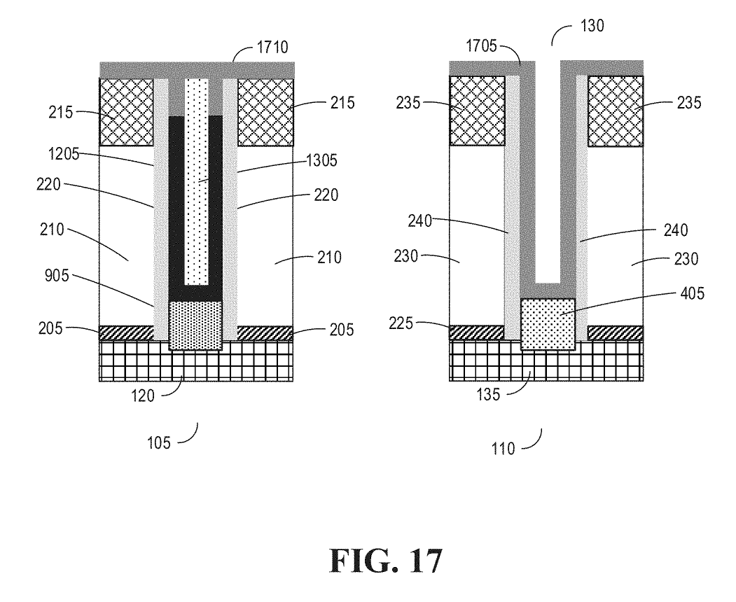

In FIG. 17, nickel-platinum (NiPt) alloy can be deposited in the second trench region so as to line the second trench region 130 with a nickel-platinum liner 1705. During the nickel-platinum deposition process, the divots above the titanium liner 1205 are also filled with nickel-platinum, resulting in nickel-platinum divot fills 1710.

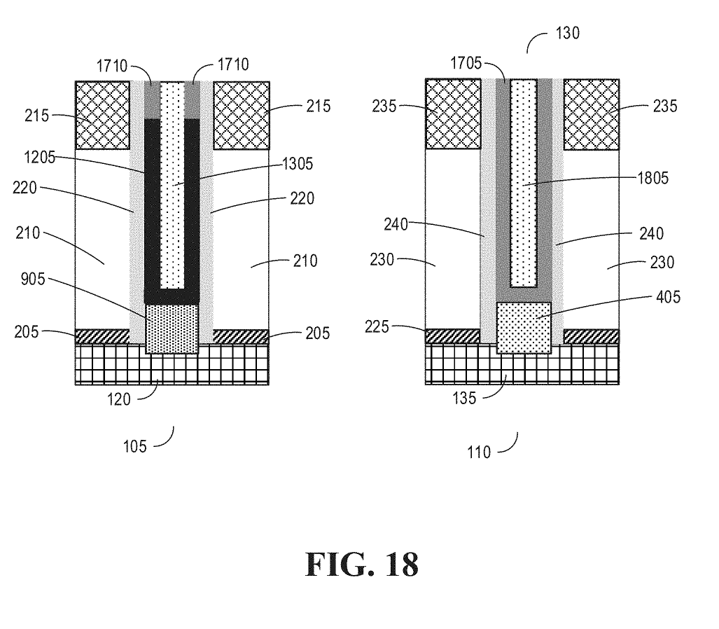

Now referring to FIG. 18, the second trench region 130 is filled with a metal (e.g., tungsten, cobalt, etc.), creating a second metallic filler 1805. Chemical mechanical planarization can then be used to remove any nickel-platinum lining the tops of the NFET 105 and PFET 110, as well as any topped off metal.

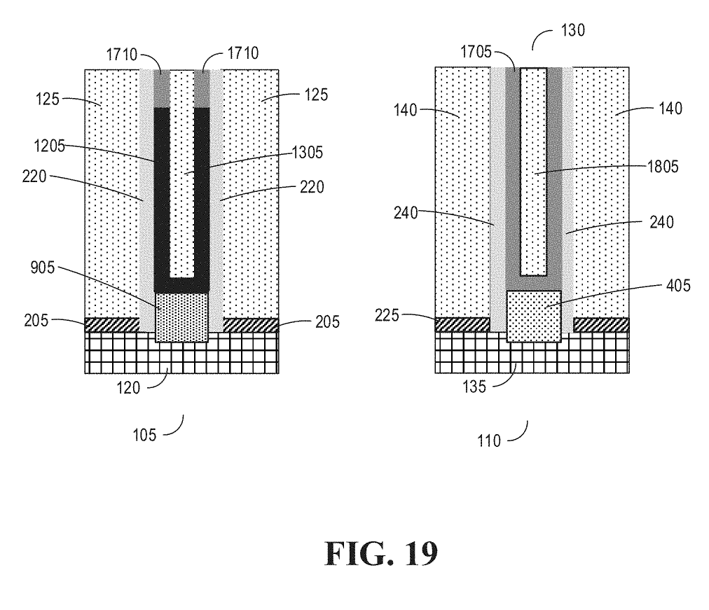

In FIG. 19, the first gate hardmask 215, second gate hardmask 235, and first dummy gate 210, and second dummy gate 230 are removed, and replaced with a first metal gate 125 and a second metal gate 140. The conductive material used in first metal gate 125 and second metal gate 140 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO₂), cobalt silicide (CoSi), nickel silicide (NiSi)), transition metal aluminides (e.g. titanium aluminide (Ti3Al), zirconium -aluminum ZrAl), tantalum carbide (TaC), tantalum magnesium carbide (TaMgC), carbon nanotube, conductive carbon, graphene, or any suitable combination of these materials. The conductive material may further comprise dopants that are incorporated during or after deposition. In some embodiments, the gate may further comprise a workfunction setting layer between the gate dielectric and gate conductor. The workfunction setting layer can be a workfunction metal (WFM). WFM can be any suitable material, including but not limited a nitride, including but not limited to titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof. In some embodiments, a conductive material or a combination of multiple conductive materials can serve as both gate conductor and WFM. The gate conductor and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc. Again, as mentioned above, in other alternative embodiments, the process can start with the real metal gates, instead of dummy gates, in which case replacing the dummy gates would be obviated. Additionally, in some example embodiments, the original, first gate dielectric 205 and second gate dielectric 225 are dummies. If so, they can also be removed and replaced by a real gate dielectric.

Thus, in the CMOS cell 100 in the resulting structure of FIG. 19, the first field effect transistor (NFET 105) comprises a first liner having a first portion (nickel-platinum divot fills 1710) and a second portion (titanium liner 1205). The second field effect transistor (PFET 110) comprises a second liner (e.g., nickel-platinum liner 1705). Here, the second portion comprises a first material (e.g., titanium), and the first portion and second liner comprise a second material (e.g., nickel-platinum alloy). The first trench region 115 wall and second trench region 130 wall are defined by a spacer material (e.g., first spacer 220, second spacer 240, respectively), and the bottom of the first trench region 115 and the bottom of the second trench region 130 are defined by epitaxial regions (e.g., NFET epitaxial region 905, PFET epitaxial region 405, respectively).

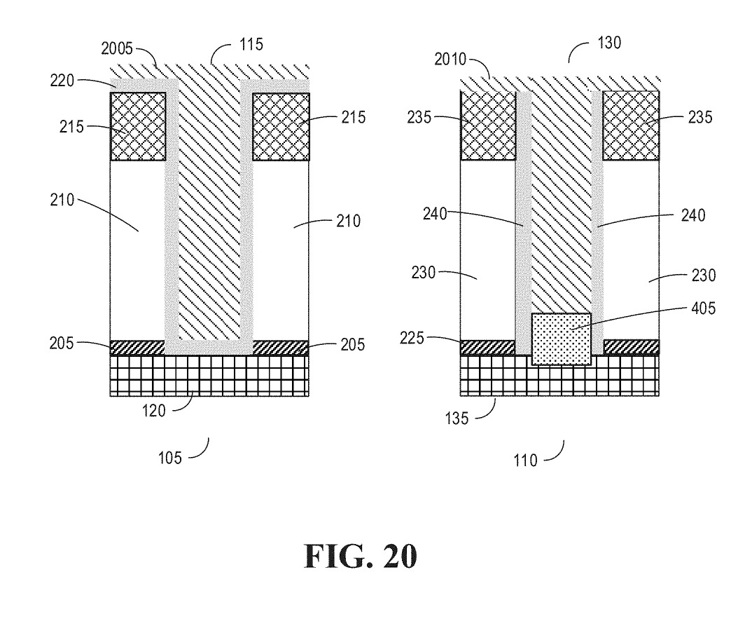

FIGS. 20-30 illustrate another example method, in accordance with the present application, for assembling (e.g., fabricating, manufacturing, etc.) an apparatus (e.g., a CMOS cell 100) that comprises a first field effect transistor (e.g., an NFET) comprising a first liner that resides in a first trench region, and a second field effect transistor (e.g., a PFET) comprising a second liner that resides in a second trench region. The first liner comprises a first material and the second liner can comprise a second material. The first trench region wall and the second trench region wall are defined by a spacer material, and the first trench region bottom and the second trench region bottom are defined by epitaxial regions.

The early stages of the example fabrication process described in FIGS. 20-30 can be similar to that of FIGS. 2-4. In FIG. 20, the method differs from FIG. 5, however, in that instead of a film of SiN or amorphous carbon lining the NFET 105 and PFET 110 trench regions, similar material (e.g., SiN, amorphous carbon) is used to fill (or plug) the first trench region 115 and the second trench region 130 (and this material can also overflow to cover the top of the NFET 105 and PFET 110), creating a first sacrificial filler 2005 and a second sacrificial filler 2010. Just as the second film 510 protected the PFET epitaxial region 405, the second sacrificial filler 2010 can protect the PFET epitaxial region 405 in further fabrication stages described below.

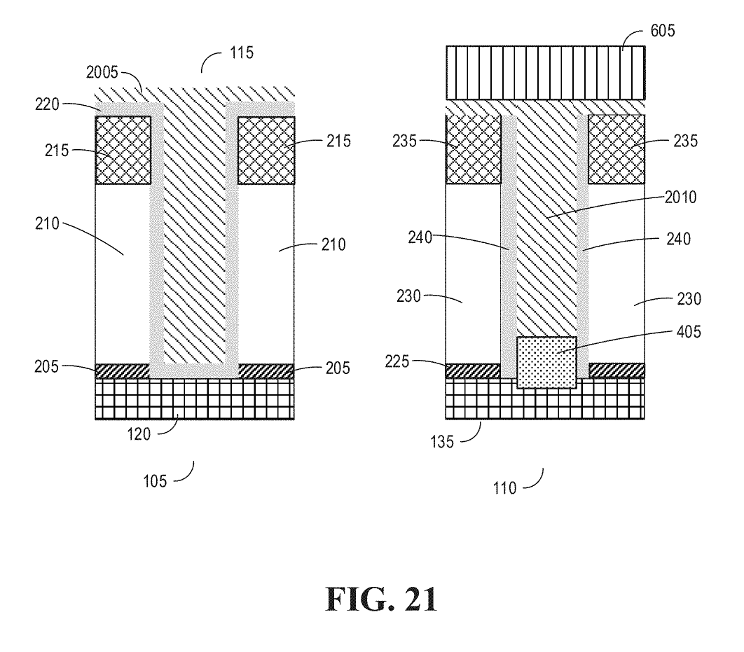

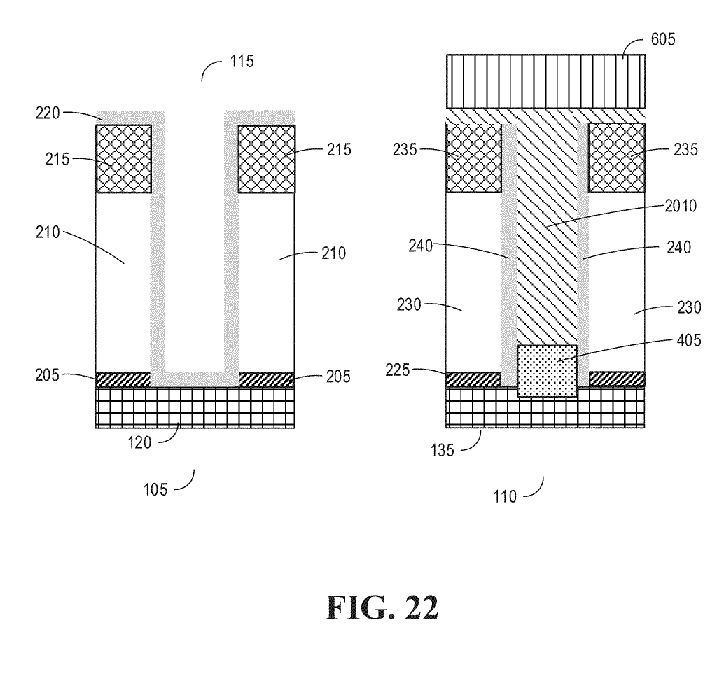

In FIG. 21, the second mask 605 can be applied so as to cover the second sacrificial filler 2010, just as in FIG. 6 it covered and protected the second film 510 during the removal of the first sacrificial filler 2005 in FIG. 22.

As shown in FIG. 22, the first sacrificial filler 2005 can be removed (e.g., by etching).

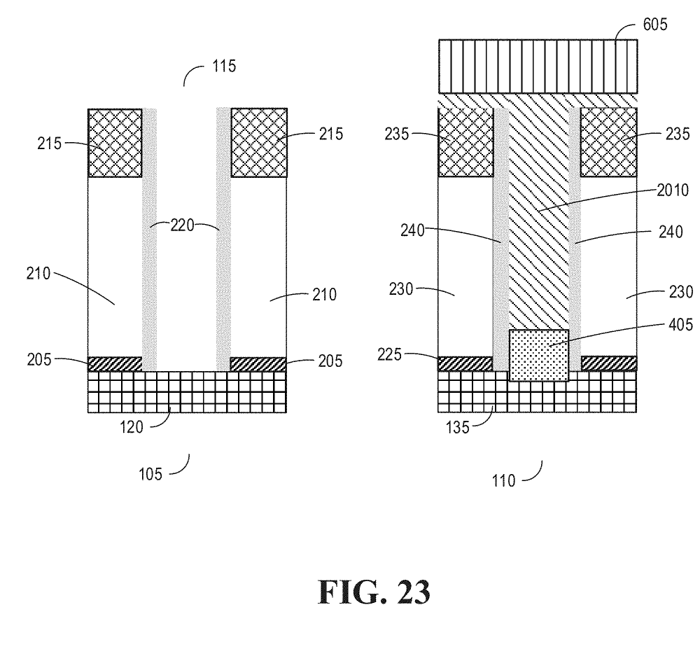

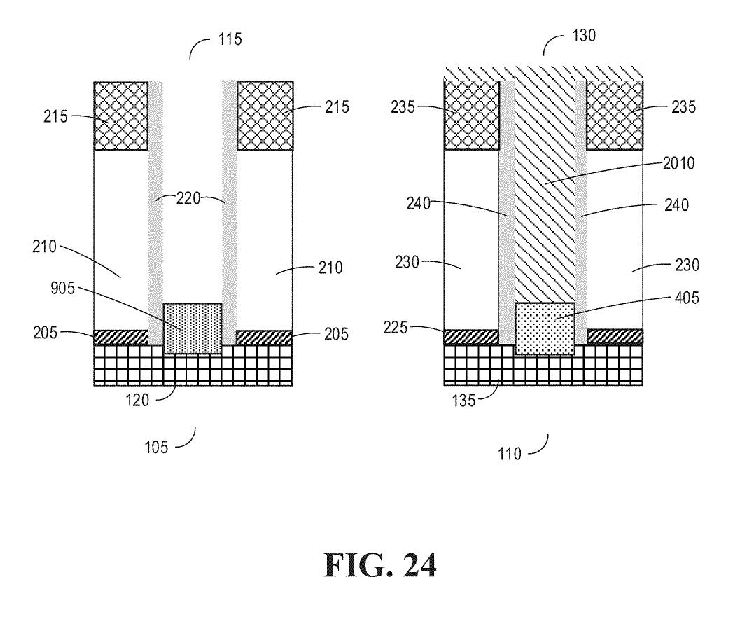

In FIG. 23, the part of the first spacer 220 on top of the NFET 105 can be removed (e.g., via a RIE). The part of the first spacer 220 that had been in contact with the first substrate 120, is also removed (e.g., using a directional etch), which exposes the first substrate 120 for growth of an epitaxial region, described in FIG. 24.

Next, as shown in FIG. 24, the second mask 605 is first removed. Then, an NFET epitaxial region 905 can be grown onto the first substrate 120. Optionally, the NFET epitaxial region 905 can be grown and punched into the first substrate 120, wherein the first substrate 120 is recessed. The NFET epitaxial region 905 can comprise a material that is different from the PFET epitaxial region 405, for example, phosphorous doped silicon, or phosphorous and carbon doped silicon.

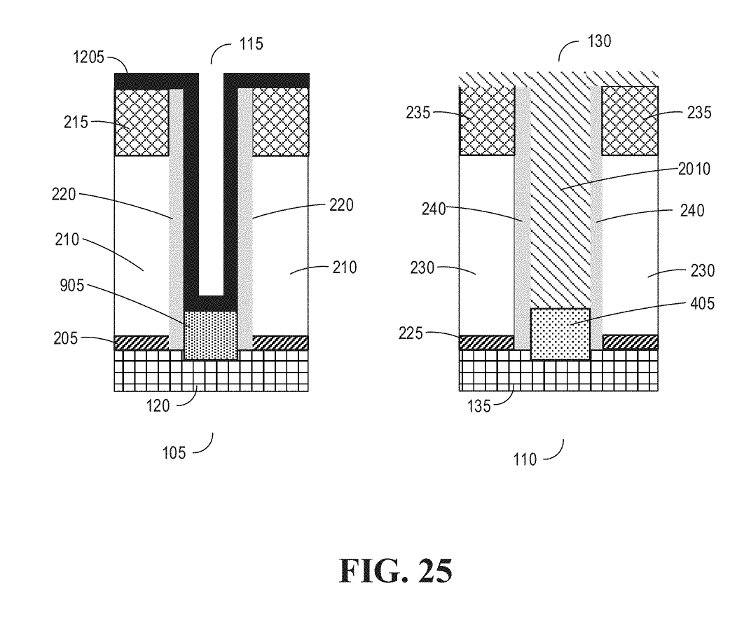

Moving to FIG. 25, a liner suitable for N-type transistors, such as titanium, can be can be deposited so as to line the first trench region 115 with a titanium liner 1205.

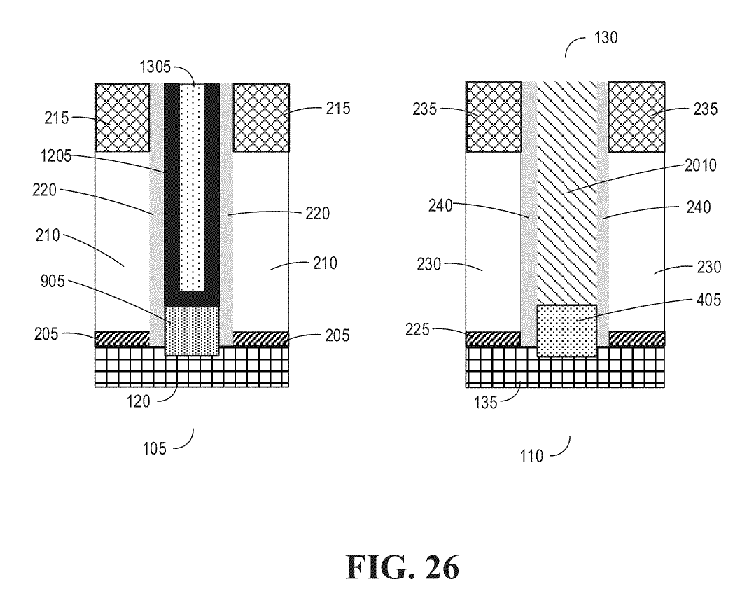

Referring now to FIG. 26, the first trench region 115 is filled with a metal (e.g., tungsten, cobalt), creating a first metallic filler 1305. Because the PFET 110 is plugged with the second sacrificial filler 2010, the metal is deposited on top of the second sacrificial filler 2010. Chemical mechanical planarization (CMP), or polishing, can be used to remove the portions of the titanium liner 1205 deposited at the top of the NFET 105, and portions of the second sacrificial filler 2010 at the top of the PFET 110.

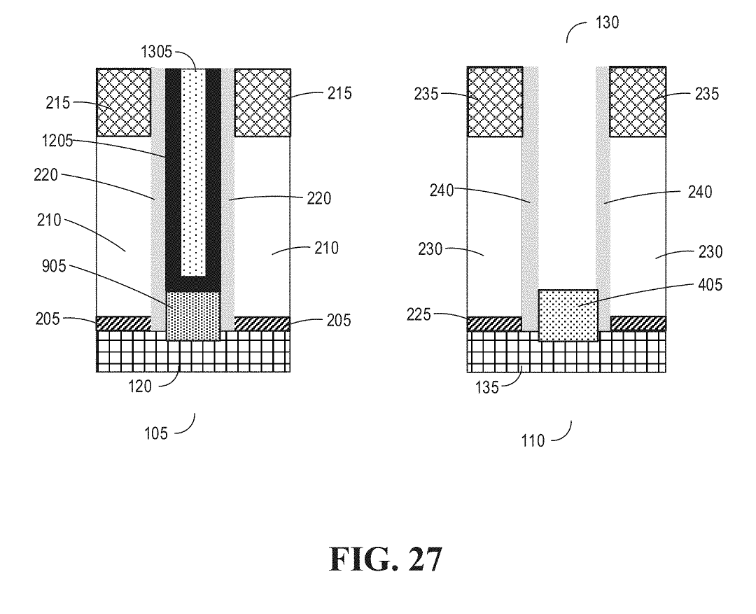

In FIG. 27, the second sacrificial filler 2010 can be removed from the second trench region 130 of the PFET 110.

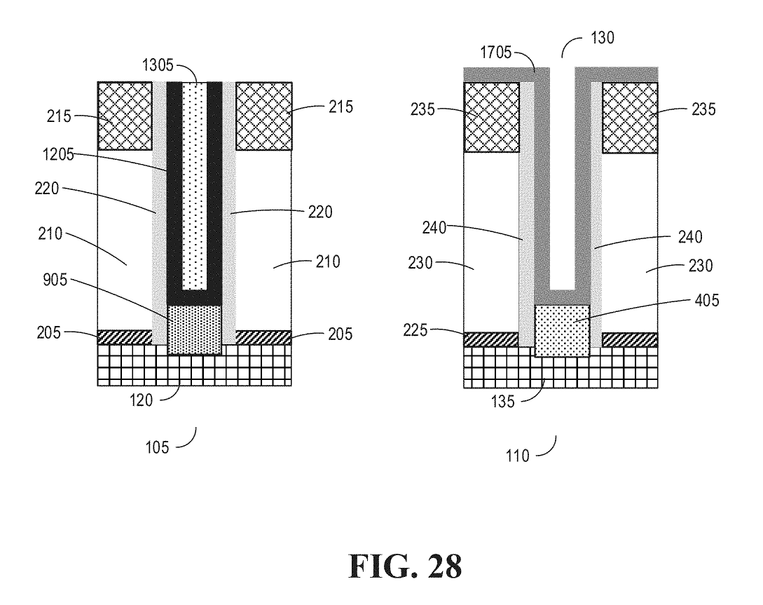

Moving now to FIG. 28, after removal of the second sacrificial filler 2010, a nickel-platinum alloy can now be deposited so as to line the second trench region 130, creating a nickel-platinum liner 1705.

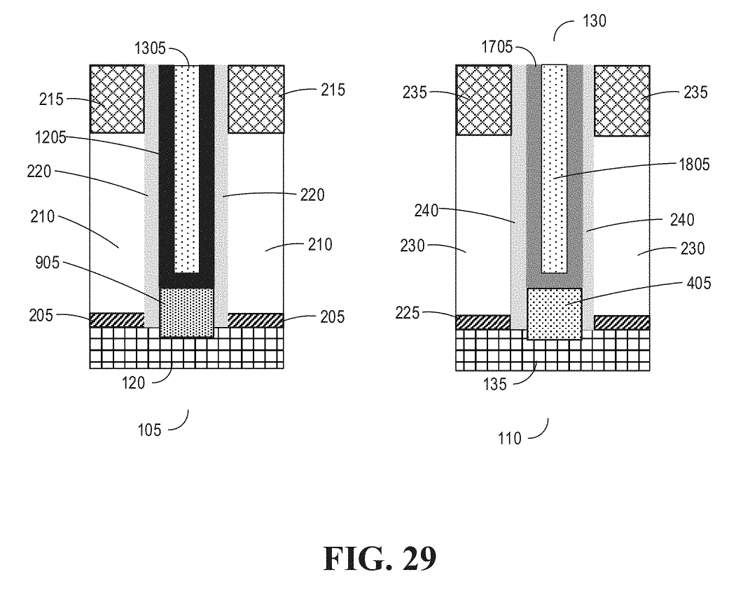

Now referring to FIG. 29, the second trench region 130 is filled with a metal (e.g., tungsten, cobalt, etc.), creating a second metallic filler 1805. Chemical mechanical planarization can then be used to remove any nickel-platinum lining the tops of the NFET 105 and PFET 110, as well as any topped off metal.

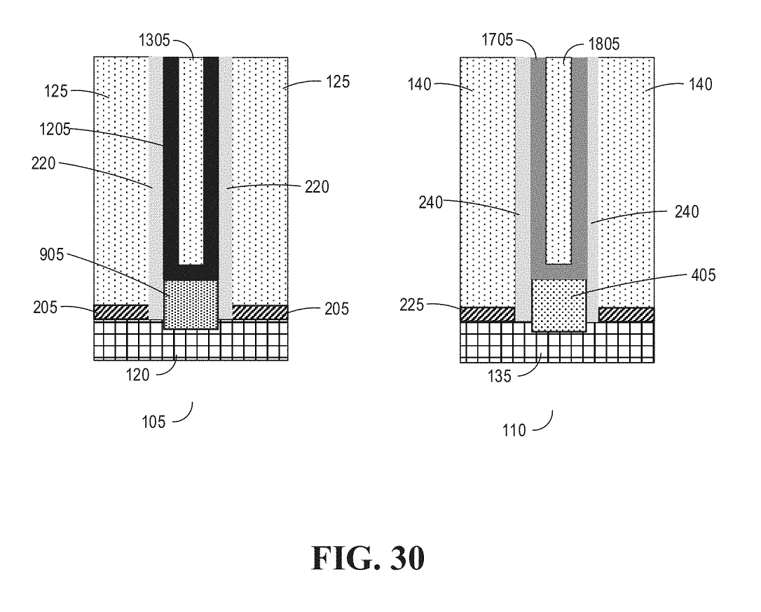

In FIG. 30, the first gate hardmask 215, second gate hardmask 235, and first dummy gate 210, and second dummy gate 230 are removed, and replaced with a first metal gate 125 and a second metal gate 140. Again, as mentioned above, in other alternative embodiments, the process can start with the real metal gates, instead of dummy gates, in which case replacing the dummy gates would be obviated. The conductive material used in first metal gate 125 and second metal gate 140 can comprise any suitable conducting material, as described above with respect to FIG. 19. Additionally, in some example embodiments, the original, first gate dielectric 205 is a dummy. If so, it can also be removed and replaced by a real gate dielectric.

The resulting embodiment of the CMOS cell 100 fabricated as described in FIGS. 20-30 thus comprises a first field effect transistor (e.g., NFET 105) comprising a first liner (e.g., titanium liner 1205) that resides in a first trench region (first trench region 115), and a second field effect transistor (e.g., PFET 110) comprising a second liner (nickel-platinum liner 1705) that resides in a second trench region (e.g., second trench region 130. The first liner comprises a first material (titanium) and the second liner can comprise a second material (nickel-platinum). The walls of first trench region 115 are defined by first spacer 220 and the walls of the second trench region 130 are defined by second spacer 240. The bottom of the first trench region 115 is defined by NFET epitaxial region 905, and the bottom of the second trench region is defined by PFET epitaxial region 405.

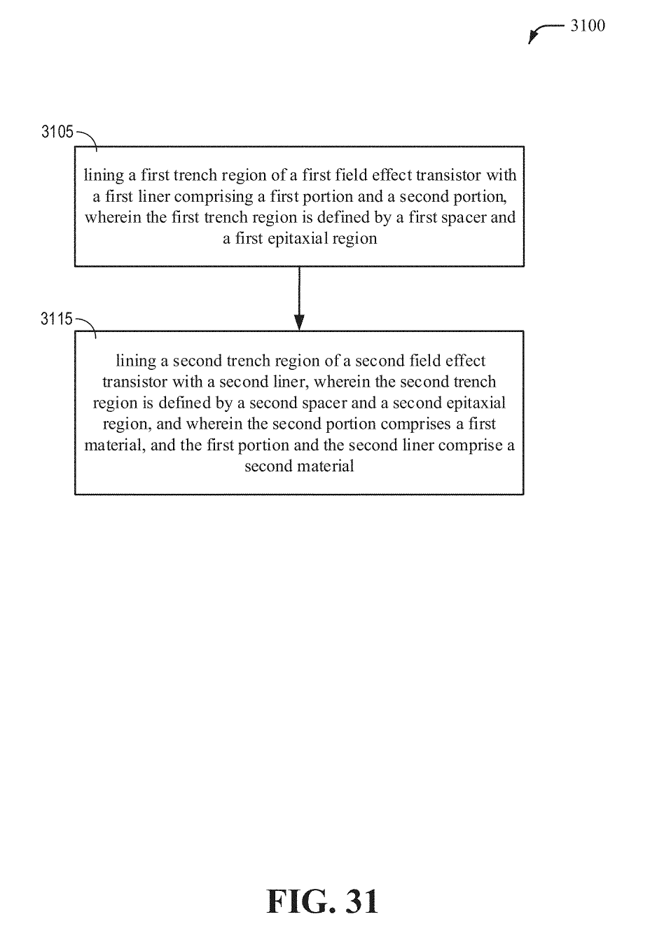

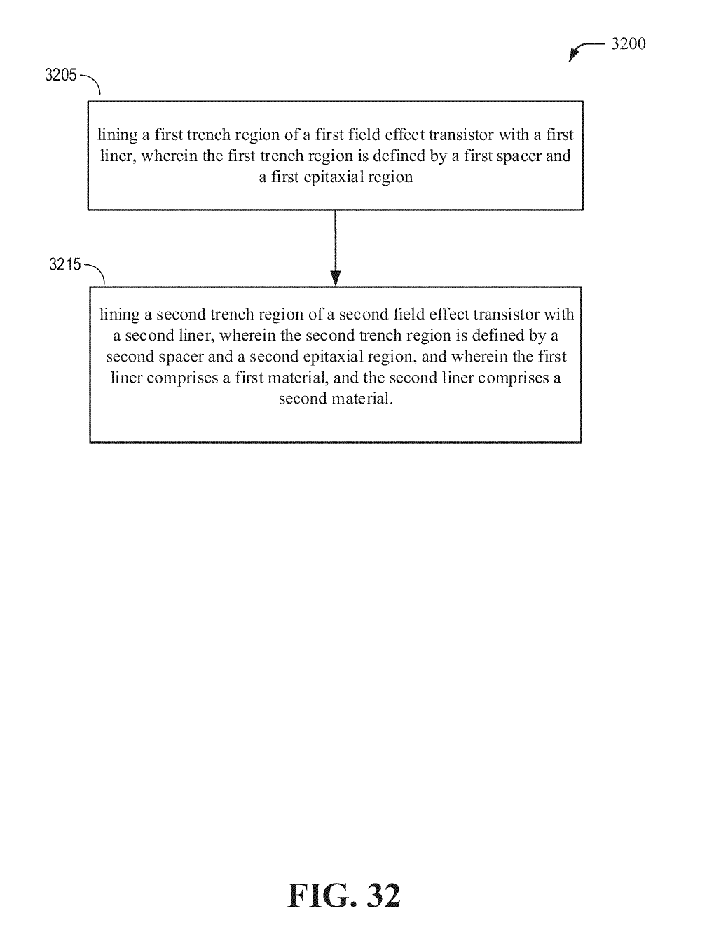

In non-limiting example embodiments, a computing device (or system) (e.g., computer 3312) is provided comprising one or more processors and one or more memories that stores executable instructions that, when executed by the one or more processors, can facilitate performance of the operations as described herein, including the non-limiting methods as illustrated in method 3100 of FIG. 31, and method 3200 of FIG. 32. As a non-limiting example, the one or more processors can facilitate performance of the methods by directing or controlling one or more equipment operable to perform chip assembly. Various example aspects of these methods have been described above with respect FIGS. 2 through 30, and is also described herein with respect to FIGS. 31 and 32.

FIG. 31 illustrates a method 3100 of an example, non-limiting method (e.g., operations) that facilitates assembly of a CMOS cell (e.g., CMOS cell 100), in accordance with one or more embodiments described herein. The example method 3100 can, at 3105, comprise lining a first trench region (e.g., first trench region 115) of a first field effect transistor (e.g., NFET 105) with a first liner comprising a first portion (e.g., nickel-platinum divot fills 1710) and a second portion (e.g., titanium liner 1205), wherein the first trench region is defined by a first spacer (e.g., first spacer 220) and a first epitaxial region (e.g., NFET epitaxial region 905). The example method 3100 can further comprise, at 3115, lining a second trench region (e.g., second trench region 130) of a second field effect transistor (e.g., PFET 110) with a second liner (e.g., nickel-platinum liner 1705), wherein the second trench region is defined by a second spacer (e.g., second spacer 240) and a second epitaxial region (PFET epitaxial region 405), and wherein the second portion comprises a first material (e.g., titanium), and the first portion and the second liner comprise a second material (e.g., nickel-platinum alloy). Both the first trench region and the second trench region can be filled with a metal (e.g., tungsten or cobalt).

Moving to FIG. 32, the method 3200 can at 3205 comprise lining a first trench region (e.g., first trench region 115) of a first field effect transistor (e.g., NFET 105) with a first liner (e.g., titanium liner 1205), wherein the first trench region is defined by a first spacer (e.g., first spacer 220) and a first epitaxial region (e.g., NFET epitaxial region 905). The method 3200, at 3215, can further comprise lining a second trench region (e.g., second trench region 130) of a second field effect transistor (e.g., PFET 110) with a second liner (e.g., nickel-platinum liner 1705), wherein the second trench region is defined by a second spacer (e.g., second spacer 240) and a second epitaxial region (e.g., PFET epitaxial region 405), and wherein the first liner comprises a first material (titanium), and the second liner comprises a second material (nickel -platinum alloy). Both the first trench region and the second trench region can be filled with a metal (e.g., tungsten or cobalt).

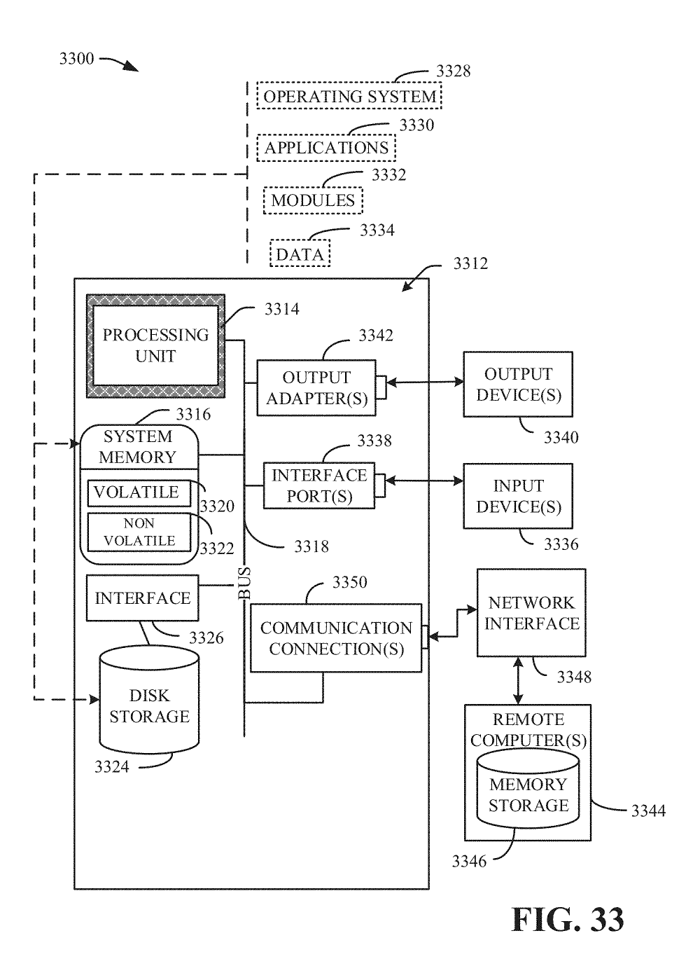

In order to provide a context for the various aspects of the disclosed subject matter, FIG. 33 as well as the following discussion are intended to provide a general description of a suitable environment in which the various aspects of the disclosed subject matter can be implemented. FIG. 33 illustrates a block diagram of an example, non-limiting operating environment in which one or more embodiments described herein can be facilitated. Repetitive description of like elements employed in other embodiments described herein is omitted for sake of brevity.

With reference to FIG. 33, a suitable operating environment 3300 for implementing various aspects of this disclosure can also include a computer 3312. The computer 3312 can also include a processing unit 3314, a system memory 3316, and a system bus 3318. The system bus 3318 couples system components including, but not limited to, the system memory 3316 to the processing unit 3314. The processing unit 3314 can be any of various available processors. Dual microprocessors and other multiprocessor architectures also can be employed as the processing unit 3314. The system bus 3318 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire (IEEE 1394), and Small Computer Systems Interface (SCSI).

The system memory 3316 can also include volatile memory 3320 and nonvolatile memory 3322. The basic input/output system (BIOS), containing the basic routines to transfer information between elements within the computer 3312, such as during start-up, is stored in nonvolatile memory 3322. Computer 3312 can also include removable/non-removable, volatile/non-volatile computer storage media. FIG. 33 illustrates, for example, a disk storage 3324. Disk storage 3324 can also include, but is not limited to, devices like a magnetic disk drive, floppy disk drive, tape drive, Jaz drive, Zip drive, LS-100 drive, flash memory card, or memory stick. The disk storage 3324 also can include storage media separately or in combination with other storage media. To facilitate connection of the disk storage 3324 to the system bus 3318, a removable or non-removable interface is typically used, such as interface 3326. FIG. 33 also depicts software that acts as an intermediary between users and the basic computer resources described in the suitable operating environment 3300. Such software can also include, for example, an operating system 3328. Operating system 3328, which can be stored on disk storage 3324, acts to control and allocate resources of the computer 3312.

System applications 3330 take advantage of the management of resources by operating system 3328 through program modules 3332 and program data 3334, e.g., stored either in system memory 3316 or on disk storage 3324. It is to be appreciated that this disclosure can be implemented with various operating systems or combinations of operating systems. A user enters commands or information into the computer 3312 through input device(s) 3336. Input devices 3336 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 3314 through the system bus 3318 via interface port(s) 3338. Interface port(s) 3338 include, for example, a serial port, a parallel port, a game port, and a universal serial bus (USB). Output device(s) 3340 use some of the same type of ports as input device(s) 3336. Thus, for example, a USB port can be used to provide input to computer 3312, and to output information from computer 3312 to an output device 3340. Output adapter 3342 is provided to illustrate that an output device 3340 like monitors, speakers, and printers, among other output devices, might require special adapters. The output adapter 3342 can include, by way of illustration and not limitation, video and sound cards that provide a means of connection between the output device 3340 and the system bus 3318. It should be noted that other devices and/or systems of devices provide both input and output capabilities such as remote computer(s) 3344.

Computer 3312 can operate in a networked environment using logical connections to one or more remote computers, such as remote computer(s) 3344. The remote computer(s) 3344 can be a computer, a server, a router, a network PC, a workstation, a microprocessor based appliance, a peer device or other common network node and the like, and typically can also include many or all of the elements described relative to computer 3312. For purposes of brevity, only a memory storage device 3346 is illustrated with remote computer(s) 3344. Remote computer(s) 3344 is logically connected to computer 3312 through a network interface 3348 and then physically connected via communication connection 3350. Network interface 3348 encompasses wire and/or wireless communication networks such as local-area networks (LAN), wide-area networks (WAN), cellular networks, etc. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). Communication connection(s) 3350 refers to the hardware/software employed to connect the network interface 3348 to the system bus 3318. While communication connection 3350 is shown for illustrative clarity inside computer 3312, it can also be external to computer 3312. The hardware/software for connection to the network interface 3348 can also include, for exemplary purposes only, internal and external technologies such as, modems including regular telephone grade modems, cable modems and DSL modems, ISDN adapters, and Ethernet cards.

The present invention may be a system, a method, an apparatus and/or a computer program product at any possible technical detail level of integration. The computer program product can include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand -alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, etc. that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer -implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The description of the various embodiments of the present invention have been presented for purpose of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

Further, what has been described above include mere examples of devices and methods. It is, of course, not possible to describe every conceivable combination of components or methods for purposes of describing this disclosure, but one of ordinary skill in the art can recognize that many further combinations and permutations of this disclosure are possible. Furthermore, to the extent that the terms “include,” “have,” “possess,” and the like are used in the detailed description, claims, appendices and drawings such terms are intended to be inclusive in a manner similar to the term “comprising” as “comprising” is interpreted when employed as a transitional word in a claim.

1. A device, comprising:
a first field effect transistor comprising a first liner comprising a first portion and a second portion, wherein the first liner resides in a first trench region that is defined by a first spacer and a first epitaxial region; and
a second field effect transistor comprising a second liner that resides in a second trench region that is defined by a second spacer and a second epitaxial region, wherein the second portion comprises a first material, and the first portion and the second liner comprise a second material.

2. The device of claim 1, wherein the first material comprises titanium, and the second material comprises a nickel-platinum alloy.

3. The device of claim 1, wherein the first trench region and the second trench region are filled with a metal.

4. The device of claim 1, further comprising a first substrate associated with the first field effect transistor, and a second substrate associated with the second field effect transistor.

5. The device of claim 4, wherein the first epitaxial region is in contact with the first substrate.

6. The device of claim 4, wherein the second epitaxial region is in contact with the second substrate.

7. The device of claim 1, wherein the first field effect transistor comprises a n -type field effect transistor, and the second field effect transistor comprises a p-type field effect transistor.

8. A device comprising:
a first field effect transistor comprising a first liner that resides in a first trench region that is defined by a first spacer and a first epitaxial region;
a second field effect transistor comprising a second liner that resides in a second trench region that is defined by a second spacer and a second epitaxial region, wherein the first liner comprises a first material and the second liner comprises a second material; and
a first substrate associated with the first field effect transistor, and a second substrate associated with the second field effect transistor, wherein the first substrate is distinct from the second substrate.

9. The device of claim 8, wherein the first material comprises titanium, and the second material comprises a nickel-platinum alloy.

10. The device of claim 8, wherein the first trench region and the second trench region are filled with a metal.

11. (canceled)

12. The device of claim 1, wherein the first epitaxial region is in contact with the first substrate.

13. The device of claim 1, wherein the second epitaxial region is in contact with the second substrate.

14. The device of claim 8, wherein the first field effect transistor comprises a n -type field effect transistor, and the second field effect transistor comprises a p-type field effect transistor.

15. A method, comprising:
lining a first trench region of a first field effect transistor with a first liner comprising a first portion and a second portion, wherein the first trench region is defined by a first spacer and a first epitaxial region; and
lining a second trench region of a second field effect transistor with a second liner, wherein the second trench region is defined by a second spacer and a second epitaxial region, and wherein the second portion comprises a first material, and the first portion and the second liner comprise a second material.

16. The method of claim 15, wherein the first material comprises titanium, and the second material comprises a nickel-platinum alloy.

17. The method of claim 15, wherein the first field effect transistor comprises an n-type field effect transistor, and the second field effect transistor comprises a p-type field effect transistor.

18. The method of claim 15, further comprising filling the first trench region and the second trench region with a metal.

19. The method of claim 18, wherein the metal comprises tungsten.

20. The method of claim 18, wherein the metal comprises cobalt.
